(19) United States
(12) Patent Application Publication
(10) Pub. No.: US 2015/0020870 A1
(43) Pub. Date: Jan. 22, 2015

(54) SOLAR CELL MODULE

(71) Applicant: HONDA MOTOR CO., LTD., Minato-ku, Tokyo (JP)

(72) Inventors: Shinya Agatsuma, Hagagun (JP); Sachio Suzuki, Hagagun (JP)

(21) Appl. No.: 14/377,955

(22) PCT Filed: Jan. 23, 2013
(86) PCT No.: PCT/JP2013/051291

§ 371 Date: Aug. 11, 2014

(30) Foreign Application Priority Data
Feb. 14, 2012 (JP) 2012-029783

(51) Int. Cl. H01L 31/02; H01L 31/048

(52) U.S. Cl. CPC H01L 31/02008; H01L 31/0488
USPC 136/251

(57) ABSTRACT

A solar cell module is provided in which production efficiency and reliability are improved by realizing wire connection without complicating wiring from the solar cell element to the terminal box, in a solar cell module having a glass-facing-glass structure. The solar cell module includes a square substrate on which a solar cell element is formed on one surface thereof, a cathode arranged on one end side part of the square substrate, an anode arranged on the other side part of the square substrate, and two terminal boxes arranged on the other surface of the square substrate, which is the opposite surface of the solar cell element side, wherein the one terminal box is connected to the cathode and two cathode cables are drawn from this terminal box, and the other terminal box is connected to the anode and two anode cables are drawn from this terminal box.

### TECHNICAL FIELD

The present invention relates to solar cell modules, and in particular, relates to a solar cell module in which wiring can be efficiently arranged.

### BACKGROUND ART

A solar cell is generally classified as a single-crystal silicon solar cell, a poly-crystal solar cell, a thin-film solar cell, etc. Among these, the thin-film type solar cell has been developed and has been commercialized, since it has an advantage in that the amount of raw material used is less than for other types of solar cells for the same power output, and an advantage in that production process is easier and less energy is required.

A chalcopyrite-type thin-film solar cell, which is a kind of thin-film type solar cell, has a CIGS layer including a chalcopyrite-based compound (for example, Cu (In₁₋ₓGaₓ)Se₂, hereinafter referred to as CIGS) as a p-type light-absorbing layer, comprises a substrate, a back surface electrode layer, a p-type light-absorbing layer, an n-type buffer layer and a transparent electrode layer as a basic structure, and generates electric power from the back surface electrode layer and the transparent electrode layer by irradiating light thereon.

FIG. 1A is a conceptual view showing a typical chalcopyrite-type thin film solar cell having such a CIGS layer as a light-absorbing layer. In this solar cell, although not shown and reference numeral omitted, a back surface electrode layer functioning as a cathode is formed on the substrate 10 by sputtering or the like. A light-absorbing layer containing Cu—In—Ga—Se (hereinafter both the p-type light-absorbing layer and the n-type buffer layer are combined and simply referred to as a light-absorbing layer) is formed on the back surface electrode layer, and a transparent electrode layer is formed thereon. In FIG. 1A, the thin film solar cell having these layers is shown as a solar cell element 20. In the solar cell element 20, a unit cell which is defined in a rectangular shape is multiply arranged, and they are connected in series by connecting a back surface electrode layer and a transparent electrode which are adjacent to each other.

As a structure to make a module for such a thin film solar cell, as shown in FIG. 4, a structure (frame structure) is generally known in which a cover glass 30 is stacked on a substrate 10 having a solar cell element 20 thereon via a sealing material 32, a back sheet 33 covers the side of the substrate 10 opposite to the cover glass, that is, at the upper side in the figure, and a frame 34 is arranged (see Patent Document 1 below).

Furthermore, in Patent Document 1 below, as a structure that is more simplified, as shown in FIG. 5, a structure is disclosed in which the back sheet 33 and the frame 34 are omitted, the cover glass 30 is stacked on the solar cell element 20 on the substrate glass 10, and it is sealed with seal material 32, and another seal material 31 is arranged around a circumferential part, that is, a glass-facing-glass structure. In the glass-facing-glass structure, by omitting the back sheet and frame, a thin solar cell module can be provided at low cost.

Furthermore, as a module to connect a solar cell module in series or in parallel, a module is known in which wires are gathered in a terminal box in the vicinity of center of a back surface of a light-receiving surface, and two pairs of anode and cathode cables are drawn from the terminal box, thereby enabling connecting in series or in parallel by changing adjacent modules and combination of connection (see Patent Document 2).

Furthermore, as a solar cell module which can be connected in a manner similar to that in Patent Document 2, a module is known in which two terminal boxes are arranged at a vicinity of the center of the back surface of the light-receiving surface of the module, and two pairs of anode and cathode cables are drawn from each box (see Patent Document 3).

Patent Document:

### Patent Document 1: Japanese Unexamined Patent Application Publication No. 2009-188357

Patent Document 2: Japanese Utility Model Application Publication No. Hei06 (1994)-77264

### Patent Document 3: Japanese Unexamined Patent Application Publication No. 2002-289893

### SUMMARY OF THE INVENTION

However, in the solar cell module disclosed in Patent Document 2, since it has a structure having the back sheet and the frame, a wire can be arranged via a space between the solar cell element and the back sheet, thereby gathering the wires in the one terminal box in the vicinity of the center of a back surface of the module; however, in the solar cell in which the glass-facing-glass structure is employed, since there is no space to arrange wires, it is difficult for wires to be connected in only one terminal box.

If it is possible for only one terminal box to be arranged in the vicinity of the center of the substrate by wiring from a power collector, since the back sheet does not exist, the wire should be drawn to the outside by drilling a hole directly through the glass substrate. There is a problem in that such solar cell module having a hole at the center of the substrate has lower strength.

Furthermore, in the solar cell module disclosed in Patent Document 3, since anode and cathode cables are drawn out of one terminal box and another pair of anode and cathode cables are also drawn out of the other terminal box, wiring at the back surface of the solar cell module becomes complicated, and production efficiency is low.

The present invention has been completed in view of the above circumstances, and an object of the invention is to provide a solar cell module in which production efficiency and reliability are improved by realizing wire connection without complicating wiring from the solar cell element to the terminal box, in a solar cell module having a glass-facing-glass structure.

The solar cell module of the present invention includes a square substrate on which a solar cell element is formed on one surface (front surface) thereof, a cathode arranged on one end side part of the square substrate, an anode arranged on the other side part of the square substrate, and two terminal boxes arranged on the other surface (back surface) of the square substrate, which is the opposite surface of the solar cell element side, wherein the one terminal box is connected to the cathode, and two cathode cables are drawn from this terminal box, and the other terminal box is connected to the anode, and two anode cables are drawn from this terminal box.

In the present invention, it is desirable that, in the electrode and the terminal box for each anode and cathode, an end part of the electrode is drawn and connected to a circuit inside of the terminal box.

In the present invention, it is desirable that the cathode terminal box be arranged at the end side part of the cathode side of the square substrate, and the anode terminal box is arranged at the end side part of the anode side of the square substrate.

In the present invention, it is desirable that the cathode terminal box be arranged at the end side part of cathode side of the square substrate and a corner part of the square substrate, and the anode terminal box be arranged at the end side part of anode side of the square substrate and a corner part of the square substrate.

According to the present invention, since two terminal boxes, each for an anode and a cathode, are arranged, by arranging the anode terminal box near an anode power collector and by arranging the cathode terminal box near a cathode power collector, it is not necessary to arrange and connect wires in a complicated manner, and each power collector for an anode and a cathode can be drawn to the terminal box directly.

Furthermore, since two pairs of anode cable and cathode cable are drawn from each of the anode and cathode terminal box, during connecting multiple solar cell modules in parallel, one of the two cables drawn from the anode terminal box or the cathode terminal box can be connected to the anode or cathode of an adjacent solar cell module, and the other of the two cables can be connected to the anode or cathode of another adjacent solar cell module. By repeating such a connection, the desired number of solar cell modules can be connected in parallel.

### BRIEF DESCRIPTION OF DRAWINGS

FIG. 1 shows a solar cell module of the present invention, FIG. 1A shows a light receiving surface (front surface), FIG. 1B shows a back surface, and FIG. 1C is a circuit diagram seen from the back surface.

FIG. 2 is a conceptual cross sectional view showing the solar cell module of the present invention.

FIG. 3 is a conceptual cross sectional view showing a conventional solar cell module.

FIG. 4 is a conceptual cross sectional view showing a conventional solar cell module.

FIG. 5 is a conceptual cross sectional view showing a conventional solar cell module.

### BEST MODE FOR CARRYING OUT THE INVENTION

Hereinafter the Embodiment of the invention is explained in detail with reference to the drawings.

The solar cell module structure of the present invention can be employed for any type of solar cell in existence, such as a chalcopyrite-type thin-film solar cell, a single crystal silicon solar cell, a poly crystal silicon solar cell, and an amorphous silicon solar cell. However, with respect to the silicon solar cell, since the solar cell element (silicon cell) and the substrate are separately produced, the cell can be arranged freely on the substrate, and degree of freedom in arranging wires is high from the cell to the terminal box.

On the other hand, with respect to the chalcopyrite-type thin-film solar cell, since the solar cell element is directly formed on the glass substrate, the solar cell element cannot be separated from the substrate and cannot be arranged again, and thus, it is difficult to arrange wiring. Therefore, the solar cell module structure of the present invention can be desirably used in such a thin-film solar cell.

The method for producing such a chalcopyrite-type thin-film solar cell is explained. That is, although not shown in the figure, first, a film of a back surface electrode layer comprising Mo metal or the like and functioning as an anode is formed on a substrate comprising soda lime glass (SLG) or the like by a sputtering method or the like using a Mo metal target or the like.

The back surface electrode layer is cut by a cutting means that has scribing blade on the top thereof or which has a laser, and is divided into multiple pieces via a separating groove. Next, film of a light absorbing layer precursor comprising Cu—In—Ga is formed on the back surface electrode layer, and then, by performing heat treatment in a hydrogen selenide (H₂Se) atmosphere, which is a treatment to disperse Se in the light absorbing layer precursor, a p-type light absorbing layer comprising CIGS is formed. Furthermore, a buffer layer comprising CdS, ZnS, or InS, for example, is formed on the light absorbing layer by a chemical bath deposition method, CBD method. The p-type light absorbing layer and the buffer layer are defined as the light absorbing layer.

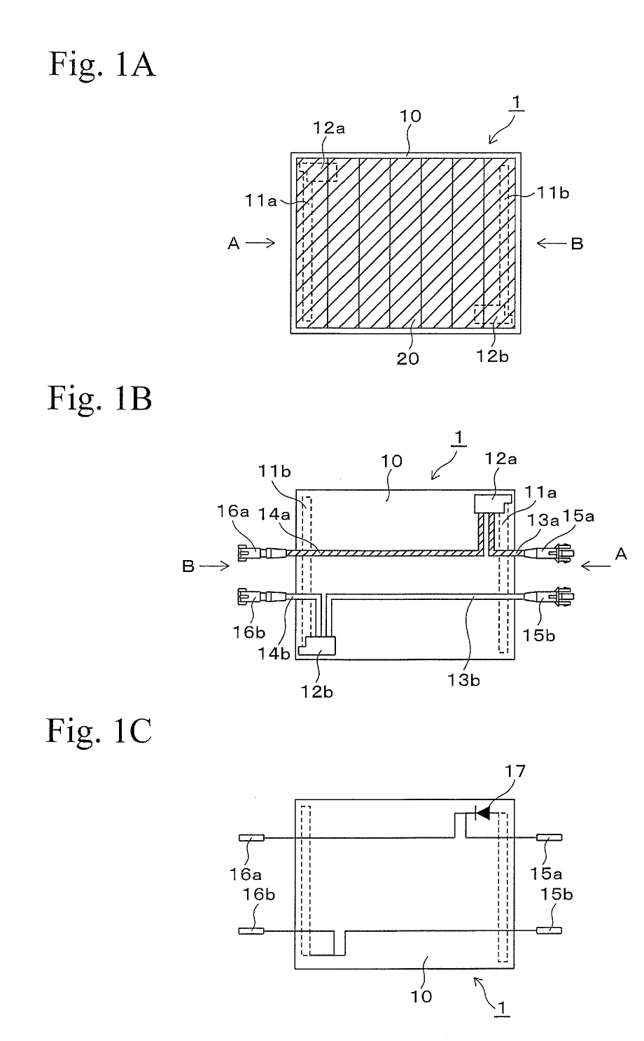

Next, the light absorbing layer is divided into multiple areas by a cutting means. In addition, a transparent electrode layer comprising ZnO, ZnAlO or the like is formed on the light absorbing layer. Finally, the transparent electrode layer and the light absorbing layer are cut together by a cutting means so as to divide the transparent electrode layer into multiple areas, thereby obtaining the thin-film solar cell 1 in which solar cell element 20 consisting of multiple unit cells having longitudinal square shape are connected in series along the left to right direction, as shown in FIG. 1A.

Subsequently, an cathode (cathode power collector) 11a is formed at end side part of the A side, and a anode (anode power collector) 11b is formed at the end side part of the B side, in FIG. 1A. A hole (not shown) is formed at both the end side part of the A side and the end side part of the B side, which are circumferential parts of the glass substrate 10, the cathode power collector 11a and the anode power collector 11b are drawn from the front surface of the glass substrate 10 via the hole parts to the back surface side.

As shown in FIG. 1B, at the back side of the glass substrate 10, an cathode terminal box 12a is arranged as a covering over the hole part of the cathode side, and an anode terminal box 12b is arranged as a covering over the hole part of the anode side. Two cathode cables (13a and 14a) are drawn from the cathode terminal box 12a, and two anode cables (13b and 14b) are drawn from the anode terminal box 12b.

An cathode connector (male type 15a, female type 16a) is arranged on top of the cathode cables 13a and 14a, and a anode connector (male type 15b, female type 16b) is arranged on top of the anode cables 13b and 14b.

Furthermore, as shown in the circuit diagram of FIG. 1C, a backflow prevention diode 17 is connected in the anode terminal box 12a.

According to the solar cell module of the present invention, in a case in which the module shown in FIG. 1B is further arranged on the A side and the B side, the cathode connector 15a of the central module and the anode connector 16a of the A side module can be connected, and the cathode connector 16a of the central module and the cathode connector 15a of the B side module can be connected. In addition, at the anode side, the anode connector 15b of the central module and the cathode connector 16b of the A side module can be connected, and the anode connector 16b of the central module and the anode connector 15b of the B side module can be connected. Similarly, adjacent modules can be connected in parallel easily by arranging a desired number of modules.

In the present invention, positions of the cathode terminal box 12a and the anode terminal box 12b, that is, positions at which holes are formed, are not particularly limited, as long as they exist on an end side part of sides where the cathode power collector 11a and the anode power collector 11b exist. For example, it can exist at a center of the end side part. However, it is desirable that it be formed in the vicinity of the corner part, as shown in FIG. 1B, since the strength of the module may be a maximal value.

In a conventional solar cell module, in order to draw all of the anode and cathode cables from a terminal box arranged in the vicinity of the center of substrate, as disclosed in Patent Document 2 for example, first, wires from a power collector should be arranged drawing to center of the substrate; however, there is no such space between the substrate and the solar cell element in the thin film solar cell, and such wiring is possible only in a solar cell having a back sheet or frame, that is, having a wiring space.

Furthermore, in a case in which such wiring is attempted in a thin film solar cell, as shown in FIG. 3, power collector 11 at the front side should be connected to a wire and the wire should be connected to the terminal box 12 via a hole part formed in the vicinity of the center of the substrate. Strength of such a solar cell having a glass-facing-glass structure is extremely low because of the hole part formed at the center.

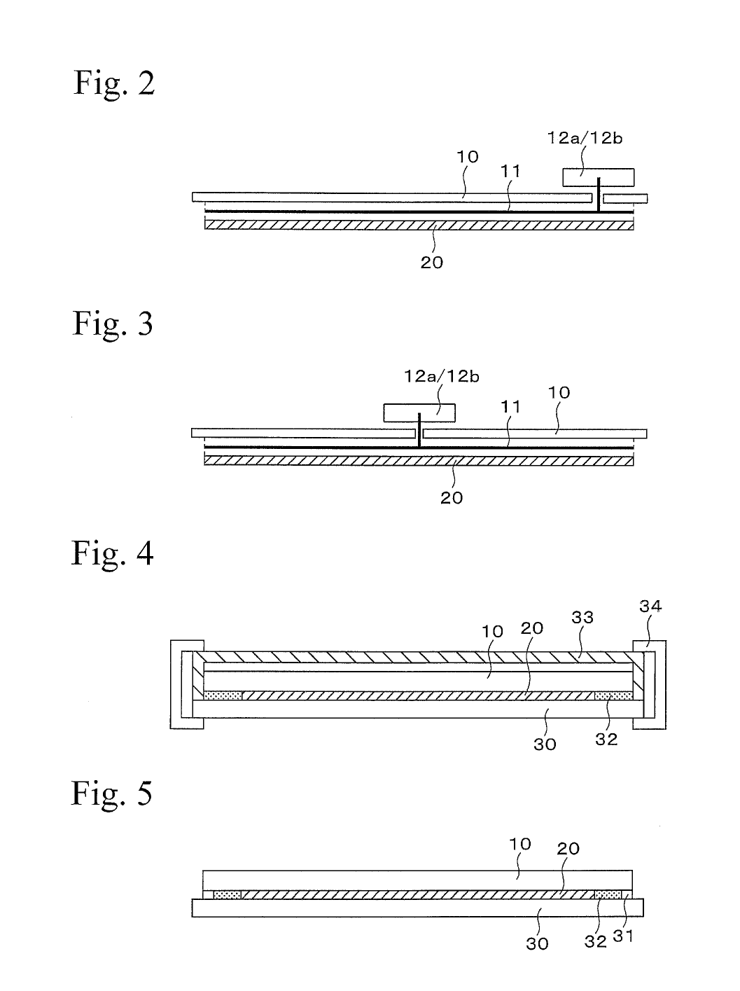

On the other hand, in the present invention, as shown in FIG. 2, since the hole part is formed at the position of the power collector, that is, in the vicinity of the end side part of the substrate 10, not only is the strength of the solar cell maintained, but it is also not necessary to connect complicated wiring from the power collector, and the wire can be directly drawn from the position of the power collector to the terminal box at the back side.

Furthermore, in a case in which a pair of anode and cathode cables are drawn from each of two terminal boxes, as disclosed in Patent Document 3, wiring from the cathode power collector to both terminal boxes, and wiring from the anode power collector to both terminal boxes, which is very complicating wiring, are required; however, such a problem is solved in the present invention, production efficiency is improved by reducing production steps, and reliability is improved by simplifying the structure.

The present invention is helpful on production of chalcopyrite-type thin film solar cell having high power generating efficiency.

### EXPLANATION OF REFERENCE NUMERALS

1: Thin film solar cell, 10: substrate, 11a: cathode power collector, 11b: anode power collector, 12a: cathode terminal box, 12b: anode terminal box, 13a, 14a: cathode cable, 13b, 14b: anode cable, 15a: cathode connector (male), 16a: cathode connector (female), 15b: anode connector (male), 16b: anode connector (female), 17: diode, 20: solar cell element, 30: cover glass, 31: seal material, 32: seal material, 33: back sheet, 34: frame.

1. A solar cell module comprising:
a glass square substrate on which a solar cell element is formed on one surface (front surface) thereof,
a cathode arranged on one end side part of the square substrate,
an anode arranged on the other side part of the square substrate,
two terminal boxes arranged on the other surface of the square substrate, which is the opposite surface of the solar cell element side,
a cover glass stacked on the solar cell element on the square substrate, and
a sealing material arranged at circumferential part of the square substrate and the cover glass,
wherein the one terminal box is arranged at the end side part of anode side of the square substrate and is connected to the cathode which is drawn to a circuit inside of the terminal box for anode via a hole formed at the end side part of anode side,
two cathode cables are drawn from the terminal box for cathode,
the other terminal box arranged at the end side part of anode side of the square substrate and is connected to the anode which is drawn to a circuit inside of the terminal box for cathode via a hole formed at the end side part of anode side, and
two anode cables are drawn from the terminal box for anode.

2-3. (canceled)

4. The solar cell module according to claim 1, wherein the cathode terminal box is arranged at the end side part of the cathode side of the square substrate and a corner part of the square substrate, and the anode terminal box is arranged at the end side part of the anode side of the square substrate and a corner part of the square substrate.
